(19) United States
(12) Patent Application Publication
(10) Pub. No.: US 2010/0220041 A1
(43) Pub. Date: Sep. 2, 2010

(54) Optoelectronic Device

(75) Inventor: Euan C. Smith, Cambridgeshire (GB)

Correspondence Address: MARSHALL, GERSTEIN & BORUN LLP, 233 SOUTH WACKER DRIVE, 6300 WILLIS TOWER, CHICAGO, IL, 60606-6357, US

(73) Assignee: CAMBRIDGE DISPLAY TECHNOLOGY LIMITED, Cambridgeshire (GB)

(21) Appl. No.: 12/675,076

(22) PCT Filed: Sep. 26, 2008
(86) PCT No.: PCT/EP2008/062969

§ 371 Date: Mar. 30, 2010

(30) Foreign Application Priority Data
Sep. 28, 2007 (GB) 0719020.0

(51) Int. Cl. G09G 3/32; H01L 31/12

(52) U.S. Cl. 345/82; 257/80; 257/E33.076

(57) ABSTRACT

A passive matrix display comprising an array of diodes disposed between a plurality of anode lines and a plurality of cathode lines, wherein at least some of the diodes are emissive diodes which are orientated in a forward direction relative to the cathode and anode lines and others of the diodes are sensing diodes orientated in a reverse direction relative to the cathode and anode lines.

### FIELD OF INVENTION

This invention relates to optoelectronic devices, displays and drive circuitry for the same.

### BACKGROUND OF INVENTION

Various types of optoelectronic displays are known in the art. One type comprises a matrix of Light Emitting Diodes (LEDs), for example in an organic or inorganic monochromatic display or a multicoloured display.

One class of opto-electrical devices for optoelectronic displays is that using an organic material for light emission (or detection in the case of photovoltaic cells and the like). The basic structure of these devices is a light emissive organic layer, for instance a film of a poly (p-phenylenevinylene) (“PPV”) or polyfluorene, sandwiched between a cathode for injecting negative charge carriers (electrons) and an anode for injecting positive charge carriers (holes) into the organic layer. The electrons and holes combine in the organic layer generating photons. In WO90/13148 the organic light-emissive material is a polymer. In U.S. Pat. No. 4,539,507 the organic light-emissive material is of the class known as small molecule materials, such as (8-hydroxyquinoline) aluminium (“Alq3”). In a practical device one of the electrodes is transparent, to allow the photons to escape the device.

A typical organic light-emissive device (“OLED”) is fabricated on a glass or plastic substrate coated with a transparent anode such as indium-tin-oxide (“ITO”). A layer of a thin film of at least one electroluminescent organic material covers the first electrode. Finally, a cathode covers the layer of electroluminescent organic material. The cathode is typically a metal or alloy and may comprise a single layer, such as aluminium, or a plurality of layers such as calcium and aluminium.

In operation, holes are injected into the device through the anode and electrons are injected into the device through the cathode. The holes and electrons combine in the organic electroluminescent layer to form an exciton which then undergoes radiative decay to give light.

Organic LEDs may be deposited on a substrate in a matrix of pixels to form a single or multi-colour pixellated display. A multicoloured display may be constructed using groups of red, green, and blue emitting pixels. So-called active matrix displays have a memory element, typically a storage capacitor and a transistor, associated with each pixel. So-called passive matrix displays have no such memory element and instead are repetitively scanned to give the impression of a steady image.

FIG. 1 shows a passive matrix display comprising an array of light-emitting diodes. The light-emitting diodes are disposed between, and connected to, a plurality of anode lines and a plurality of cathode lines which provide an electrical bias to drive the diodes. The anode lines are positively biased and the cathode lines are negatively biased relative to each other.

FIG. 2 shows a vertical cross section through an example of an OLED device 100. In an active matrix display, part of the area of a pixel is occupied by associated drive circuitry (not shown in FIG. 1). The structure of the device is somewhat simplified for the purposes of illustration.

The OLED 100 comprises a substrate 102, typically 0.7 mm or 1.1 mm glass but optionally clear plastic, on which an anode layer 106 has been deposited. The anode layer typically comprises around 150 nm thickness of ITO (indium tin oxide), over which is provided a metal contact layer, typically around 500 nm of aluminium, sometimes referred to as anode metal. Glass substrates coated with ITO and contact metal may be purchased from Corning, USA. The contact metal (and optionally the ITO) is patterned as desired so that it does not obscure the display, by a conventional process of photolithography followed by etching.

A substantially transparent hole transport layer 108a is provided over the anode metal, followed by an electroluminescent layer 108b. Banks 112 may be formed on the substrate, for example from positive or negative photoresist material, to define wells 114 into which these active organic layers may be selectively deposited, for example by a droplet deposition or inkjet printing technique. The wells thus define light emitting areas or pixels of the display.

A cathode layer 110 is then applied by, say, physical vapour deposition. The cathode layer typically comprises a low work function metal such as calcium or barium covered with a thicker, capping layer of aluminium and optionally including an additional layer immediately adjacent the electroluminescent layer, such as a layer of lithium fluoride, for improved electron energy level matching.

In certain applications it is desirable to provide a device which has light sensing capability rather than light-emitting capability, e.g. photovoltaic cells, cameras, and the like. Light sensing diode devices are known and are very similar in structure to light-emissive diode devices. The light-sensing diodes essentially work in reverse to the light-emissive diodes described above. A photon of light which impinges on a light sensing diode device generates an exciton comprising a hole and an electron in an opto-electically active layer of the device. If a bias is applied to the opto-electrically active layer via opposing electrodes, the hole and electron may be extracted from the opto-electrically active layer via the opposing electrodes yielding a current which can be sensed by suitable sensing circuitry. Holes will be extracted via the negatively biased electrode while electrons will be extracted via the positively biased electrode. Suitable materials are selected for the electrodes to readily extract the holes and electrons without requiring a large bias. For the positively biased electrode, electron accepting materials should be selected whereas for the negatively biased electrode, hole accepting materials should be selected. Usually, materials which are good hole injectors in light-emissive devices (anode materials) will also function as good hole acceptors in light-sensing devices. Similarly, materials which are good electron injectors (cathode materials) in light-emissive devices will function as good electron acceptors in light-sensing devices. Thus, for sensing devices, the negatively biased electrode (the cathode) is advantageously made of an anode material in order to readily accept holes, and the positively biased electrode (the anode) is advantageously made of a cathode material.

In certain applications it is desirable to provide a device in which both light-emissive pixels and light sensor/detector pixels are disposed. An example of such a device is a touch screen which may comprise a plurality of light-emissive pixels in an array which also incorporates a plurality of light-sensing pixels. When a user's finger is disposed adjacent such a display, light emitted from the display may be reflected back and detected by one or more of the sensing pixels adjacent the user's finger. Alternatively, another actuating mechanism such as an external light source, e.g. a light pen, can be used to actuate the light-sensing pixels in such a display. The position of the actuator will determine which sensing pixels are actuated. This functionality can be used, for example, to select an icon displayed on the device or to select an option from a menu displayed on the device.

Active matrix light emissive diode display devices which comprise both light-emissive pixels and light sensor pixels are known. However, they include complex circuitry and as such can require a complicated manufacturing process and have a relatively high cost of production as a consequence.

Embodiments of the present invention aim to solve the aforementioned problems in the prior art.

### SUMMARY OF THE PRESENT INVENTION

The present applicant set out to provide a more simple and cheap display device which incorporates both light-emissive and light-sensing functionality for use as a touch screen or the like.

In order to achieve this aim, the present applicant has recognised that one solution to this problem is to use a passive matrix light-emissive diode display (rather than an active matrix display) similar to that illustrated in FIG. 1 but with at least some of the diodes being used for detecting light incident on the display. That is, sensing circuitry may be connected to at least some of the diodes in order to detect light impinging on the device.

One problem with this solution is that a passive matrix diode display does not comprise individual circuitry for each diode as in an active matrix display. Rather, the diodes are disposed between a common array of cathode and anode lines and are biased in the same direction when scanned. Thus, if a photon of light impinges on one of diodes and an electron-hole pair (an exciton) is generated in the opto-electrically active layer of the diode, the electron will be attracted towards the positively biased electrode which will be the hole injecting electrode made of a hole injecting material. Similarly, the hole generated by the photon of light will be attracted to the negatively biased electrode which will be the electron injecting electrode made of an electron injecting material. As the hole injecting material will not readily accept electrons, and the electron injecting material will not readily accept holes, then little or no current will be generated by the charge carriers formed by the incident light. As such, the diodes will not function as effective sensors. Furthermore, as the diodes will also be emitting (if they are forward biased) then the functionality of emission and detection is not separable and can lead to turning on of diodes which are not desired to be switched on.

The present applicant has realized that the aforementioned problem could be partially solved by reverse biasing some of the diodes in the display. For example, referring back to FIG. 1, in a simple standard passive matrix display the pixels may be scanned by holding a first row electrode at a negative potential (relative to the columns) and applying a positive bias to each column electrode to turn on each diode in turn across the row. Subsequently, the second row electrode can be held at a negative potential and a positive bias applied to each column electrode to turn on each diode in turn across the second row and so on. However, if some of the column electrodes are given a negative bias relative to the rows (i.e. at a more negative potential such that the electrons will flow from these column electrodes to the row electrodes) then the diodes in these columns will be reverse biased and may be able to function as detectors rather than emitters. For example, alternate columns of diodes could be reverse biased in this manner.

One problem with the aforementioned arrangement is that because the row electrodes are held at a relatively negative potential in order to forward bias the emissive diodes, a relatively large negative potential must be applied to column electrodes in order to reverse bias the detector diodes. This is inefficient and leads to increased power consumption and reduced lifetime of the diodes. Furthermore, the sensitivity of the detecting diodes may be poor.

Accordingly, while the present applicant has recognised that the aforementioned solution is feasible, there are problems with this solution as discussed.

In light of the above, and in accordance with an aspect of the present invention, there is provided a passive matrix display comprising an array of diodes disposed between a plurality of anode lines and a plurality of cathode lines, wherein at least some of the diodes are emissive diodes which are orientated in a forward direction relative to the cathode and anode lines and others of the diodes are sensing diodes orientated in a reverse direction relative to the cathode and anode lines.

The anode lines can be arranged to be positively biased relative to the cathode lines. Thus, the display may comprise drive circuitry connected to the anode and cathode lines to positively bias the anode lines relative to the cathode lines.

The diodes may comprise an anode, a cathode, and an opto-electrically active material disposed therebetween.

The diodes which are orientated in the forward direction for emission of light have their anode disposed adjacent to, and in electrical connection with, the anode lines, and their cathode disposed adjacent to, and in electrical connection with, the cathode lines. The anode of these diodes is made of a material which is suitable for injecting positive charge carriers (e.g. holes) and the cathode of these diodes is made of a material which is suitable for injecting negative charge carriers (e.g. electrons).

In contrast, the diodes which are orientated in the reverse direction for detection of light have their layer of anode disposed adjacent to, and in electrical connection with, the cathode lines, and their cathode disposed adjacent to, and in electrical connection with, the anode lines. The anode of these diodes is made of a material which is suitable for accepting positive charge carriers (e.g. holes) and the cathode of these diodes is made of a material which is suitable for accepting negative charge carriers (e.g. electrons). In other words, the diodes for detecting light are effectively turned around so as to be orientated in an opposite direction to the emissive diodes relative to the cathode and anode lines providing the electrical bias to the diodes. That is, the sensing diodes are physically reversed relative to cathode and anode lines biasing the diodes. This contrast with the arrangement illustrated in FIG. 1 where all the diodes are orientated in the same direction.

It will be noted that in the context of the present invention, in relation to the sensing diodes the terms cathode and anode refer to the intrinsic properties of the materials used for these layers. Thus, the cathode is made of a material which readily accepts electrons, while the anode is made of a material with readily accepts holes. In contrast to the emissive diodes, in the sensing diodes the cathode is actually contacted with an anode line and is thus positively biased whereas the anode is actually contacted with a cathode line and is thus negatively biased.

The aforementioned embodiment solves the problems previously outlined with regard to prior art active matrix displays in that additional circuitry components are not required and therefore the display is easier to manufacture. Accordingly, the displays of the present invention have lower production costs. Furthermore, such an arrangement overcomes the aforementioned problems with passive matrix displays which have all their diodes orientated in the same direction relative to the cathode and anode lines. The displays of the present invention will be more efficient, have lower power consumption, increased lifetime, and better sensitivity, and switching on of diodes which are not desired to be switched on will be alleviated.

With the aforementioned arrangement, there is no requirement to reverse the biasing of some of scanning/driving lines to achieve sensing functionality because the diodes themselves are reversed. Thus, all the scanning lines can be biased in the same direction and reverse biasing of the sensing diodes will naturally occur due to their reversed orientation relative to the cathode and anode lines.

Reversing the orientation of the sensing diodes relative to the cathode and anode lines can be achieved in two different ways: (1) the layers of the sensing diodes can be reversed relative to the emissive diodes whereby the anode lines are disposed on one side of the diode array, the cathode lines are disposed on an opposite side of the diode array, the emissive diodes are formed with anode material adjacent the anode lines and cathode material adjacent the cathode lines, and the sensing diodes are formed with anode material adjacent the cathode lines and cathode material adjacent the anode lines; or (2) the layers of the sensing diodes are disposed in the same order as the emissive diodes but the cathode and anode lines are routed whereby the cathode lines contact the cathodes of the emissive diodes but the anodes of the sensing diodes and the anode lines are disposed such that they contact the anodes of the emissive diodes but the cathodes of the sensing diodes. As such, either the layered structure of the diodes may be reversed or the cathode and anode lines can be re-routed to achieve opposite orientation of the sensing and emissive diodes relative to the cathode and anode lines.

In one embodiment of the present invention, one or more layers of the sensing diodes are doped in order to reverse the orientation of the sensing diodes.

In order to provide efficient injection/acceptance of electrons into/out of the opto-electrically active layer, the cathodes may have a workfunction of less than 3.5 eV, more preferably less than 3.2 eV, most preferably less than 3 eV.

In order to provide efficient injection/acceptance of holes into/out of the opto-electrically active layer, the anodes may have a workfunction of more than 3.5 eV, more preferably more than 4.0 eV, most preferably more than 4.5 eV.

However, in accordance with one embodiment the material used for the anode and cathode of the sensing diodes may be the same. Preferably, this material is selected to have an intermediate workfunction such that it can function as either an electron acceptor or a hole acceptor. For example, the material may have a workfunction in the range 3 to 4.5 eV, more preferably in the range 3.2 to 4.3 eV, most preferably 3.5 to 4.3 eV. An example of such a material is aluminium.

The cathode and anode lines may be arranged in columns and rows. Some of the columns/rows may comprise diodes orientated in the reverse direction for sensing. For example, alternate columns or rows may comprise diodes orientated in the reverse direction for sensing.

The sensing diodes may be arranged side-by-side with the emissive diodes on a substrate. Alternatively, the sensing diodes may be arranged above or below the emissive diodes in a stacked arrangement. For example, the sensing diodes may be stacked on top of the emissive diodes. This can result in a more sensitive touch screen display.

The stacked arrangement can increase accuracy for detecting light reflected back into the device from an emissive diode. Furthermore, the emissive and/or sensing area of a display can be increased as the number of emissive and/or sensing diodes need not be diluted which is the case if the emissive and sensing diodes are disposed side-by-side. Thus, more sensors and emitters may be employed for the same size display when compared with a side-by-side arrangement.

In contrast, a side-by-side arrangement for the sensing and emissive diodes may be advantageous in a producing a thin display, for example a thin flexible display, when compared with a vertically stacked arrangement. Furthermore, absorption of light within the display (e.g. light emitted from the opto-electrically active layer) may be reduced in the side-by-side arrangement when compared with the stacked arrangement.

The sensing and/or emissive diodes may comprise additional charge injection and/or charge transporting layers between the opto-electrically active layer and the anode and/or cathode. For example, a hole transporting material can be provided between the anode and the opto-electrically active layer. An electron transporting material can be provided between the cathode and the opto-electrically active layer. Additional layers such as a hole injecting/accepting layer adjacent the anode or an electron injecting/accepting layer adjacent the cathode may also be provided.

According to another aspect of the present invention there is provided a light emissive diode device comprising a light emissive diode and a light sensing diode stacked one on top of the other. This may be a simple device such as an illuminated touch sensitive button or a more complex device such as the displays discussed previously. As before, each diode may comprise a layer of anode material, a layer of cathode material, and an opto-electrically active material disposed therebetween. Drive circuitry can be adapted to negatively bias the layer of cathode material in the light emissive diode, positively bias the layer of anode material in the light emissive diode, negatively bias the layer of anode material in the light sensing diode, and positively bias the layer of cathode material in the light sensing diode.

### BRIEF SUMMARY OF THE DRAWINGS

Embodiments of the present invention will now be described by way of example only with reference to the accompanying drawings in which:

FIG. 1 shows a standard arrangement of diodes in a typical prior art passive matrix array, wherein all diodes are orientated in the same direction;

FIG. 2 shows a vertical cross section through a passive matrix display such as that illustrated in FIG. 1;

FIG. 3 shows an array structure of sensing diodes and emissive diodes in a passive matrix display in accordance with an embodiment of the present invention;

FIG. 4 shows the cross section of an OLED device in accordance with an embodiment of the present invention, wherein reversing the orientation of the sensing diodes is brought about by re-routing of the anode and cathode lines;

FIG. 5 shows the cross section of an OLED device in accordance with an embodiment of the present invention, wherein reversing the orientation of the sensing diodes is brought about by reversing the layered structure of the diodes;

FIG. 6 shows the energy levels of an emissive diode in accordance with an embodiment of the present invention;

FIG. 7 shows the energy levels of a sensing diode wherein the orientation of the diode has been reversed in accordance with an embodiment of the present invention;

FIG. 8 shows the energy levels of a sensing diode in which the same material is used for both electrodes in accordance with an embodiment of the present invention;

FIG. 9 shows a cross-section of a doped layer diode which can be used in embodiments of the present invention;

FIGS. 10a and 10b show a vertical stack arrangement of the emissive and sensing diodes in accordance with an embodiment of the present invention;

FIGS. 11a and 11b show a top-down view of the vertical stack arrangement in accordance with an embodiment of the present invention;

FIG. 12 shows a sensing diode including a polymer blend which can be used in embodiments of the present invention; and

FIG. 13 shows another sensing diode which can be used in embodiments of the present invention.

### DETAILED DESCRIPTION OF PREFERRED EMBODIMENTS

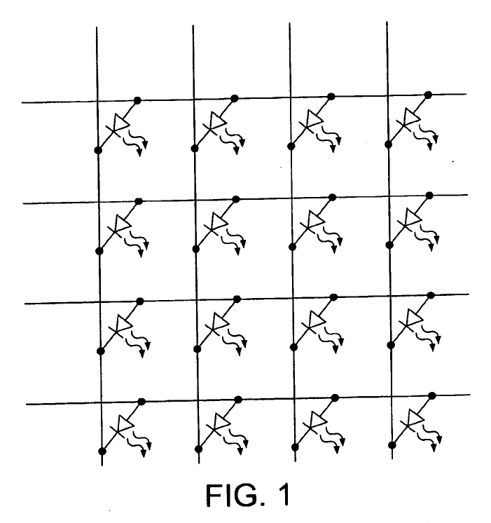

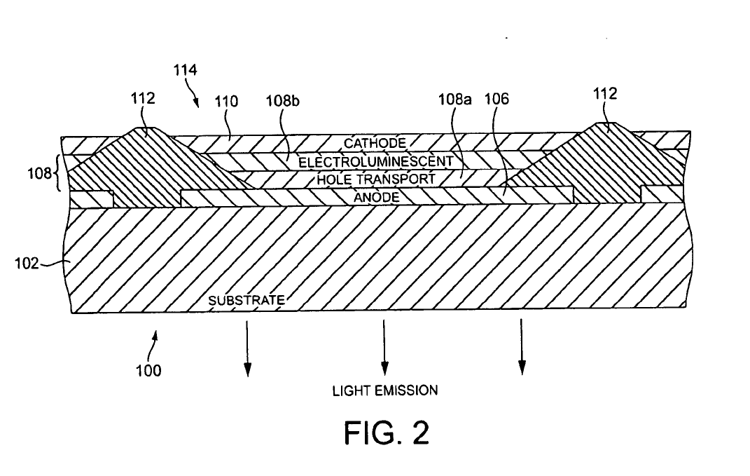

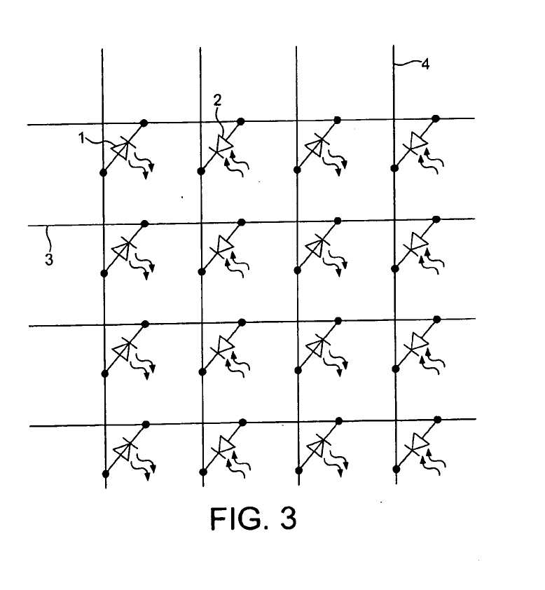

FIG. 3 shows the array structure of emissive diodes 1 and sensing diodes 2 in a passive matrix display in accordance with an embodiment of the present invention. As can be seen by cross-referencing with the prior art arrangement shown in FIG. 1, the arrangement in FIG. 3 differs in that the sensing diodes 2 are orientated in an opposite direction to the emissive diodes 1. The diodes are disposed between rows of cathode lines 3 and columns of anode lines 4.

The structure is addressed one row at a time. Three voltage levels can be defined. A ground level, Vgnd equal to zero volts, a bias level of the sensing diodes Vs, for example 20 volts, and a typical drive voltage for the emitting diodes, Vd (although they may be current driven) which may lie between the ground level and Vs. When a row is driven it is tied to the ground level voltage and all other rows are set at Vs. The sensor columns are driven at Vs during scanning and any current generated can be measured by sensing circuitry. The emitter columns are driven at drive voltage Vd which causes electrons to flow in a forward direction and emission of light.

The sensing diodes in the off rows will have zero bias and therefore will produce little or no current from incident light.

The emissive diodes in the off rows will be reverse bias and will therefore be off. Although Vd is preferably less than Vs in order to reverse bias the emissive diodes in the off rows, Vd could be equal to Vs or greater than Vs by an amount that does not exceed the threshold voltage required to drive the emissive diodes.

The sensing diodes in the on row will be reverse bias by Vs and will therefore have an enhanced quantum efficiency for detecting light incident upon them. In holding the voltage at Vs current can be generated and detected.

The emissive diodes in the on row will be forward bias by Vd and therefore emit light.

Light emitted by the emissive diodes which falls on any object in close proximity or touching the screen will be reflected back to the sensing diodes.

As a modification to this method, the off rows could be held at Vs minus the sensing diode's built-in voltage thus quenching any photocurrent.

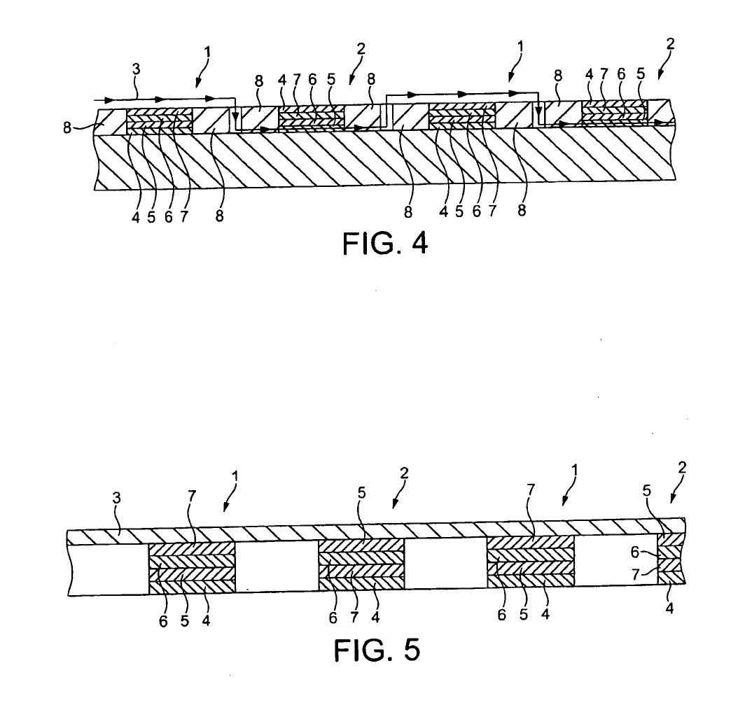

FIG. 4 shows one way in which the sensing diodes can be orientated in a reverse direction relative to the cathode and anode line. This is achieved as shown in FIG. 4 by re-routing of the anode lines 4 and the cathode lines 5 such that they alternately contact the anodes 5 and cathodes 7 of the diodes. Opto-electrically active material 6 is disposed between the anodes 5 and the cathodes 7. Each of the diodes is thus made up of a lower anode 5, an opto-electrically active layer 6 and a cathode 7. For an emissive diode 1, the cathode line 3 contacts the cathode 7 and the anode line 4 contacts the anode 5. For a sensing diode 2, the cathode line contacts the anode 5 and the anode line contacts the cathode 7. Vias may be provided in the bank material 8 to allow the electrode lines to contact alternate terminals of the diodes.

The arrangement illustrated in FIG. 4 shows alternating emissive and sensing columns. However, other arrangements can also be envisaged. For example, alternating rows could be provided or fewer sensing diodes could be provided in order to increase the number of emissive diodes in the display.

FIG. 5 shows the cross section of an OLED display in accordance with another embodiment of the present invention, wherein reversing the orientation of the sensing diodes is brought about by reversing the layered structure of the diodes. In this arrangement, the cathode lines 3 remain on one side of the diode array and the anode lines 4 remain on an opposite side of the diode array. Reverse orientation of the sensing diodes 2 is achieved by arranging the cathode material 7 adjacent the anode lines 4 and the anode material 5 adjacent the cathode lines 3. In contrast, in the emissive diodes, the anode material 5 is disposed adjacent the anode lines 4 and the cathode material 7 is disposed adjacent the cathode lines 3.

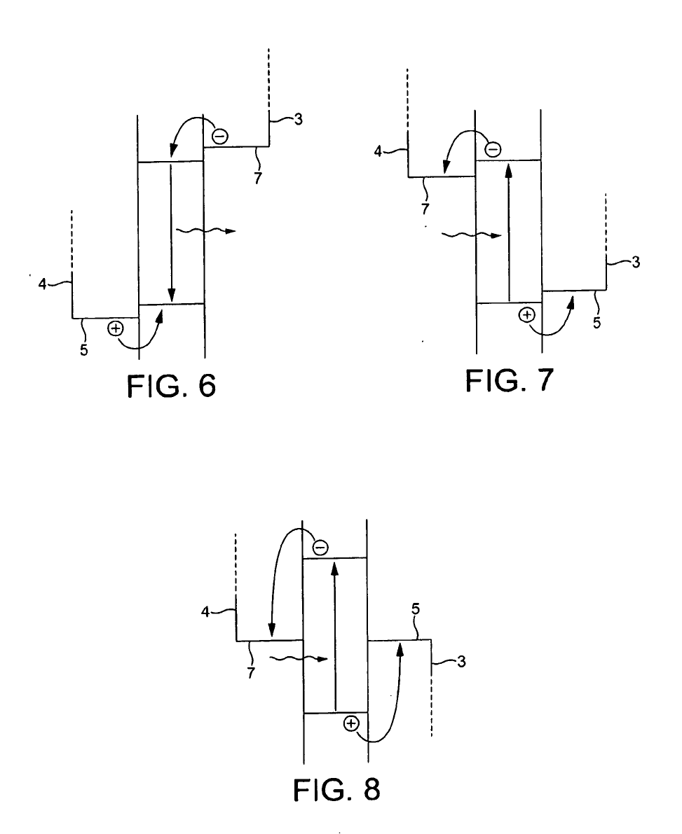

FIG. 6 shows the energy levels of an emissive diode in accordance with an embodiment of the present invention. For example, an ITO anode 5 and a barium cathode 7 may be employed. The anode 5 is positively biased by an anode line 4 and the cathode 7 is negatively biased by a cathode line 3. Accordingly, a positively charged hole is injected from the anode 5 into a HOMO level of an opto-electrically active material. Similarly, an electron is injected from the cathode 7 into LUMO level of the opto-electrically active material. The hole and electron combine in the opto-electrically active material to form an exciton and upon radiative decay of the exciton light is emitted.

FIG. 7 shows the energy levels of a sensing diode wherein the orientation of the diode has been reversed in accordance with an embodiment of the present invention. In this case, the cathode material 7 in the diode is positively biased by an anode line 4 and the anode material 5 in the diode is negatively biased by a cathode line 3. As such, when an exciton is formed in the opto-electrically active layer by absorption of photons of light, electrons will be biased towards the cathode material 7 and holes will be biased towards the anode material 5. The electrons will be accepted by the cathode material 7 and the holes will be accepted by the anode material 5. Charge thus flows out of the diode producing a current which can be detected.

FIG. 8 shows the energy levels of a sensing diode in which the same material is used for both electrodes. Aluminium may be used in this case. The diode functions in the same manner as that shown in FIG. 7. While the energy level matching of the HOMO and LUMO of the opto-electrically active material with the Fermi level of the anode and cathode material 5, 7 is not as good as in the arrangement of FIG. 7, which may thus require a larger bias voltage to generate measurable current, the simplicity of using the same materials for both electrodes may be advantageous in certain applications.

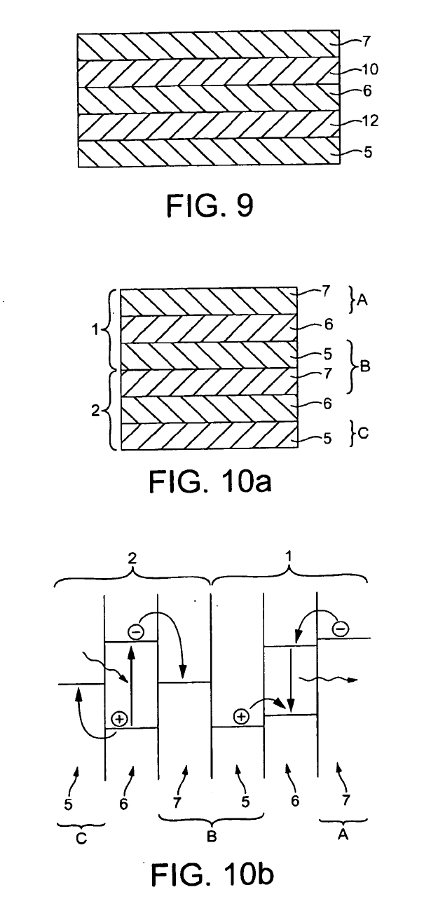

Better energy level matching can be achieved by insertion of additional charge transporting layers between the opto-electrically active layer and the electrodes. For example, FIG. 9 shows an arrangement in which a doped n-type layer 10 is disposed adjacent the cathode 7 and a doped p-type layer 12 is disposed adjacent the anode 5. One particularly useful method of manufacturing the sensing and/or emissive diode involves depositing a mixture of hole transporting material and electron transporting material from solution, the hole transporting material and the electron transporting material phase separating to form a hole transporting layer and an electron transporting layer. An opto-electrically active material 6 may also be deposited in the mixture and may phase separate into a separate layer as shown in FIG. 9 or remain in one of the hole or electron transporting layers.

FIGS. 10a shows a vertical stack arrangement of emissive and sensing diodes 1, 2. In the illustrated arrangement the emissive diode 1 is disposed on top of the sensing diode 2 although the arrangement could be reversed such that the sensing diode is disposed on top of the emissive diode.

In the stacked arrangement illustrated, the sensing diode 2 comprises a lower anode electrode 5 (e.g. aluminium) in contact with a cathode line C and is thus is negatively biased for accepting positive charge carriers from an opto-electrically active layer 6 disposed thereover. The opto-electrically active layer 6 is disposed over the lower electrode 5 and an upper cathode electrode 7 (e.g. aluminium) is disposed over the opto-electrically active layer 6. The upper cathode electrode 7 is in contact with an anode line B and is thus positively biased for accepting negative charge carriers from the opto-electrically active layer 6. In the illustrated embodiment, the anode and cathode 5, 7 of the sensing diode 2 are made of the same material, e.g. aluminium. However, they may be made of a different material as discussed previously.

Disposed over the sensing diode 2 is an anode 5 (e.g. ITO) of the emissive diode 1 which is also in contact with the anode line B and is thus positively biased for injecting positive charge carriers into an opto-electrically active layer 6 disposed thereover. A cathode 7 (e.g. barium) of the emissive diode 1 is disposed over the opto-electrically active layer 6 and is in contact with a cathode line A in order to negatively bias the cathode 7 for injecting negative charge carriers into the opto-electrically active layer 6 of the emissive diode 1.

FIG. 10b shows an energy level diagram for the arrangement shown in FIG. 10a illustrating movement of charge, emission and absorption.

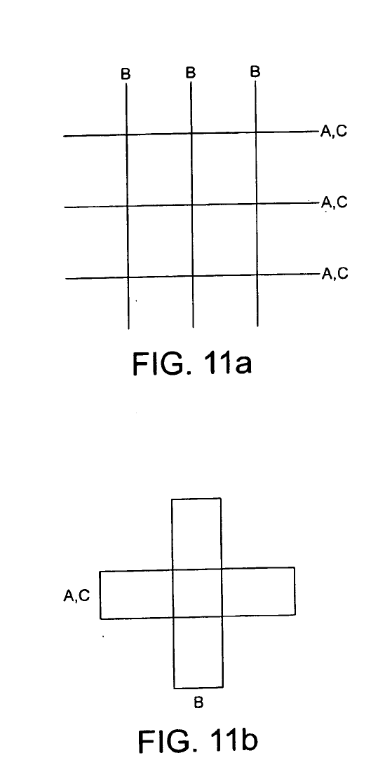

FIGS. 11a and 11b show plan views of the vertical stack arrangement indicating the orientation of the cathode lines A, C and the anode lines B.

It will be understood that other stacked arrangements are envisaged. For example, the biasing lines A, C may be anode lines which are positively biased and the biasing line B may be a cathode line which is negatively biased. In this case, the bottom electrode of the sensing diode would comprise a cathode material, the top electrode of the sensing electrode would comprise an anode material, the bottom electrode of the emissive diode would comprise a cathode material, and the top electrode of the emissive diode would comprise an anode material.

Due to the processing steps involved with forming overlying layers, buffer layers may also be employed to protect underlying layers.

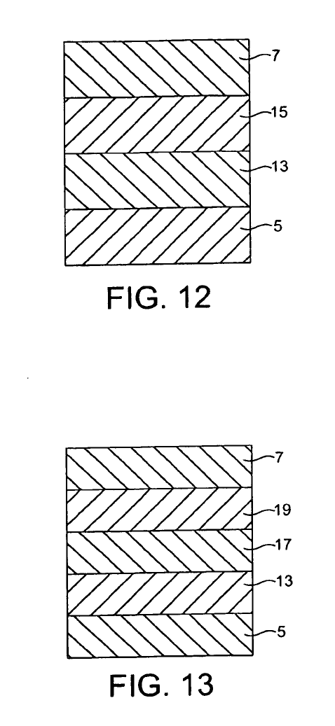

A diode comprising a polymer blend is shown in FIG. 12. The diode comprises an anode 5 (e.g. ITO), a hole injection layer (e.g. PEDOT) 13, a polymer blend layer 15 comprising an emissive component and another component such as a charge transporting component, and a cathode 7 (e.g. Al or LiF). A diode comprising a multilayer structure including an electron transport layer and a hole transporting layer is shown in FIG. 13. The diode comprises an anode 5, a hole injecting layer 13, a hole transporting layer 17, an electron transporting layer 19, and a cathode 7. These diodes may be employed for the diodes of embodiments of the present invention.

The opto-electrically active materials of the emissive diodes and sensing diodes may be selected such that the opto-electrically active material of the sensing diode does not absorb light emitted directly from the emissive diode but rather absorbs light of, for example, a different frequency generated by an external light source (e.g. a light pen) or by reflection from an external body adjacent the device. Materials for emissive and sensing diodes are well known in the art and a skilled person could readily make such a selection given the teachings of the present specification.

While this invention has been particularly shown and described with reference to preferred embodiments thereof, it will be understood by those skilled in the art that various changes in form and details may be made therein without departing from the scope of the invention as defined by the appended claims.

1. A passive matrix display comprising an array of diodes disposed between a plurality of anode lines and a plurality of cathode lines, wherein at least some of the diodes are emissive diodes which are oriented in a forward direction relative to the cathode and anode lines and others of the diodes are sensing diodes oriented in a reverse direction relative to the cathode and anode lines.

2. A passive matrix display according to claim 1, comprising drive circuitry connected to the anode lines and cathode lines and adapted to positively bias the anode lines relative to the cathode lines.

3. A passive matrix display according to claim 1, wherein each diode comprises a layer of anode material, a layer of cathode material, and an opto-electrically active material disposed therebetween.

4. A passive matrix display according to claim 3, wherein the diodes that are oriented in the forward direction for emission of light have their anode material disposed adjacent to, and in electrical connection with, the anode lines, and their cathode material disposed adjacent to, and in electrical connection with, the cathode lines, and wherein the diodes that are oriented in the reverse direction for sensing of light have their anode material disposed adjacent to, and in electrical connection with, the cathode lines, and their cathode material disposed adjacent to, and in electrical connection with, the anode lines.

5. A passive matrix display according to claim 3 4, wherein the anode lines are disposed on one side of the diode array, the cathode lines are disposed on an opposite side of the diode array, the emissive diodes are formed with anode material adjacent the anode lines and cathode material adjacent the cathode lines, and the sensing diodes are formed with anode material adjacent the cathode lines and cathode material adjacent the anode lines.

6. A passive matrix display according to claim 3 4, wherein the layers of anode and cathode material in the sensing diodes are disposed in the same order as in the emissive diodes and the cathode and anode lines are routed through the diode array whereby the cathode lines contact the cathodes of the emissive diodes and the anodes of the sensing diodes, and the anode lines contact the anodes of the emissive diodes and the cathodes of the sensing diodes.

7. A passive matrix display according to claim 3, wherein the cathode material has a workfunction of less than 3.5 eV.

8. A passive matrix display according to claim 3, wherein the anode material has a workfunction of more than 3.5 eV.

9. A passive matrix display according to claim 3, wherein the material used for the anode and cathode layers of the sensing diodes is the same.

10. A passive matrix display according to claim 9, wherein the material used for the anode and cathode layers of the sensing diodes has a workfunction in the range 3 to 4.5 eV.

11. A passive matrix display according to claim 1, wherein the cathode and anode lines are arranged in columns and rows.

12. A passive matrix display according to claim 11, wherein the diode array comprises some columns or rows of sensing diodes.

13. A passive matrix display according to claim 12, wherein the diode array comprises alternating columns or rows of sensing and emissive diodes.

14. A passive matrix display according to 1, wherein the sensing diodes are arranged side-by-side with the emissive diodes on a substrate.

15. A passive matrix display according to claim 1, wherein the sensing diodes are arranged above or below the emissive diodes in a stacked arrangement.

16. A passive matrix display according to claim 1, wherein the sensing and/or emissive diodes comprise charge injection and/or charge transporting layers.

17. A passive matrix display according to claim 1, wherein at least one layer of the sensing diodes is doped.

18. A passive matrix display according to claim 1, comprising sensing circuitry coupled to at least the anode lines and cathode lines which are in electrical contact with the sensing diodes, the sensing circuitry being adapted to sense a current generated by the sensing diodes.

19. A light emissive diode device comprising a light emissive diode and a light sensing diode stacked one on top of the other.

20. A light emissive diode device according to claim 19, wherein each diode comprises a layer of anode material, a layer of cathode material, and an opto-electrically active material disposed therebetween.

21. A light emissive diode device according to claim 20, comprising drive circuitry adapted to negatively bias the layer of cathode material in the light emissive diode, positively bias the layer of anode material in the light emissive diode, negatively bias the layer of anode material in the light sensing diode, and positively bias the layer of cathode material in the light sensing diode.

22. A passive matrix display according to claim 3, wherein the cathode material has a workfunction of less than 3.2 eV

23. A passive matrix display according to claim 3, wherein the cathode material has a workfunction of less than 3 eV.

24. A passive matrix display according to claim 3, wherein the anode material has a workfunction of more than 4.0 eV.

25. A passive matrix display according to claim 3, wherein the anode material has a workfunction of more than 4.5 eV.

26. A passive matrix display according to claim 9, wherein the material used for the anode and cathode layers of the sensing diodes has a workfunction in the range 3.2 to 4.3 eV.

27. A passive matrix display according to claim 9, wherein the material used for the anode and cathode layers of the sensing diodes has a workfunction in the range 3.5 to 4.3 eV.
